(19) United States
(12) Patent Application Publication
(10) Pub. No.: US 2013/0029123 A1
(43) Pub. Date: Jan. 31, 2013

(54) TIN OXIDE DEPOSITED BY LINEAR PLASMA ENHANCED CHEMICAL VAPOR DEPOSITION

(71) Applicant: John E. Madocks, Ashfield, MA (US)

(72) Inventor: John E. Madocks, Ashfield, MA (US)

(21) Appl. No.: 13/445,460

(22) Filed: Apr. 12, 2012

Related U.S. Application Data
(60) Provisional application No. 61/474,654, filed on Apr. 12, 2011.

(51) Int. Cl. C23C 16/513; C23C 16/40; B32B 9/00

(52) U.S. Cl. 428/220; 427/576

(57) ABSTRACT

A process for the deposition of a tin oxide film is provided that includes the decomposition of a tetravalent tin precursor under conditions of plasma enhanced chemical vapor deposition in a linear plasma source and onto a substrate moving through a plasma generated by the linear plasma source with a linear uniformity of thickness that varies by less than 5 thickness percent across the substrate. The substrate having a width of greater than 30 centimeters. The tin oxide film contains a dopant and a dopant concentration such that the film has a resistivity as a function of film deposition temperature of less than −4.6×10⁻⁵ Ohm-centimeter per degree Kelvin (T) plus 0.01 Ohm-centimeter where T is between 293 Kelvin and 673 Kelvin.

### RELATED APPLICATIONS

This application claims priority benefit of the U.S. Provisional Application Ser. No. 61/474,654 filed Apr. 12, 2011; the contents of which are hereby incorporated by reference.

### FIELD OF THE PREFERRED EMBODIMENTS

The present invention in general relates to deposition of thin coatings of tin oxide and in particular to the quality and rate of deposition of such coatings applied by plasma enhanced chemical vapor deposition (PECVD).

### BACKGROUND OF THE INVENTION

Tin oxide based films are used in a variety of applications where the optical properties of tin oxide and doped versions thereof are used in optical technologies. Crystalline tin oxide has good optical transparency and properties and is typically used in crystalline form. Additionally, crystalline tin oxide layers doped with antimony, fluorine, or oxygen vacancies are operative as transparent electrical conductors, low-emittance coatings, and frost-preventing surfaces. Many of these uses rely on free electrons originating from the ionization of dopants. As many of the desirable properties of tin oxide films relies on the ability of the film to sustain mixed conduction of ions and electrons, the quality of film deposition is particularly critical for tin oxide.

The prior art techniques for producing tin oxide films in pure or doped form have included dip coating, magnetron sputtering, spray pyrolysis, radio frequency, blow discharge CVD, air pressure CVD (APCVD), radio frequency parallel CVD, and PECVD. While all of these prior techniques are capable of producing tin oxide films, they're all characterized by at least one limitation that has limited the commercial usage of tin oxide films and in particular conductive transparent tin oxide based films. These limitations have included low deposition rate, irregular deposition thickness and large format substrates, extraneous powder formation, electrode fouling, electrode etch back requirements, high precursor costs and high resistivity in electrically conductive doped tin oxide films.

Thus, there exists a need for a process for deposition of a tin oxide film that overcomes the limitations of prior art deposition techniques. There further exists a need for tin oxide films that are produced at high deposition rates a composition including a tin oxide film on a substrate, the tin oxide film having a linear uniformity of thickness across the width of the deposited films that varies by less than five thickness percent across a film with of greater than 80 cm with the film having a low resistivity in doped form.

### SUMMARY OF THE INVENTION

A process for the deposition of a tin oxide film is also provided that includes the decomposition of a tetravalent tin precursor under conditions of plasma enhanced chemical vapor deposition in a linear plasma source and onto a substrate moving through a plasma generated by the linear plasma source, the film has a linear uniformity of thickness that varies by less than 5 thickness percent across said substrate, said substrate having a width of greater than 30 cm.

A composition is provided that includes a substrate onto which a tin oxide film is deposited. The film has a linear uniformity of thickness that varies by less than five thickness percent across the substrate width. The substrate width being greater than 30 cm. The tin oxide film contains a dopant and a dopant concentration such that the film has a resistivity as a function of film deposition temperature of less than −4.6×10⁻⁵ Ohm-centimeter per degree Kelvin (T) plus 0.01 Ohm-centimeter where T is between 293 Kelvin and 673 Kelvin.

### BRIEF DESCRIPTION OF THE DRAWINGS

FIG. 1 is a prior art schematic depicting continuous deposition of the material onto a moving substrate under a linear plasma source for PECVD;

FIG. 2 is a prior art plot of fluorine doped tin oxide for small substrates showing superior resistivity as compared to prior art deposition where stars denote inventive films and other shapes denote various prior art reported resistivity as a function of deposition temperature in degrees Celsius with the results taking into account thickness effects with various films;

FIG. 3 is a plot of sheet resistance for fluorine doped tin oxide as a function of deposition temperature for tin oxide film thicknesses of 100 nm (solid square), 500 nm (solid triangle), and 1,000 nm (solid diamond) for a carrier concentration of 2×10²⁰ per square centimeter.

FIG. 4 is a plot of transmittance as a function of wavelength for 300 mm wide sheets of inventive tin oxide having a sheet resistance of 10 Ohms per square centimeter deposited at 523 Kelvin (250° C.) compared to conventional aluminum zinc oxide having a sheet resistance of 10 Ohms per square centimeter; and conventional indium tin oxide having a sheet resistance of 12 Ohms per square centimeter and a thickness of 330 nm;

FIG. 5 is a plot of sheet resistance as a function of anneal temperature for fluorine doped tin oxide according to the present invention as compared to conventionally sputtered aluminum zinc oxide (filled diamonds); and

FIG. 6 is a plot of sheet resistance as a function of time and 90% relative humidity exposure at 50° C. for fluorine doped tin oxide according to the present invention (filled triangles) relative to conventional sputtered aluminum zinc oxide (filled square diamond).

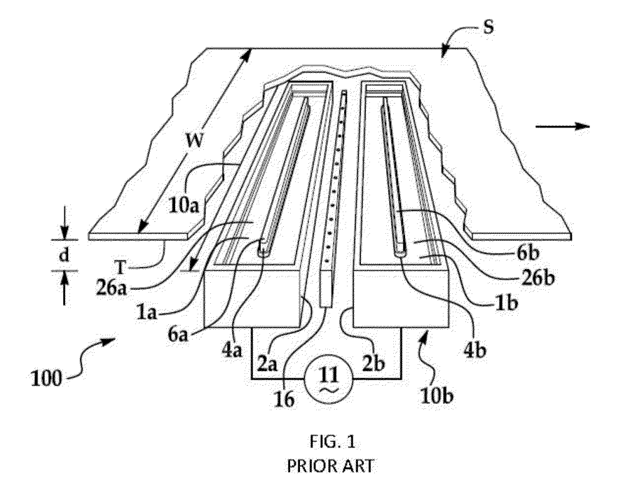

### DESCRIPTION OF THE PREFERRED EMBODIMENTS

The present invention has utility in the deposition of tin oxide films that find applications in a number of settings illustratively including photovoltaic cell manufacture. The rate of deposition and qualities of such films applied by PECVD are highly advantageous as compared to conventional techniques such as reactive sputtering. It is appreciated that in addition to producing SnO₂ having a cassiterite crystal structure, the present invention is suitable for the production of tin oxides that have different Sn:O stoichiometries including oxygen deficient formulas up to an including stoichiometric Sn(II) oxide. Additionally, it is appreciated that doped tin oxides are also readily formed according to the present invention. Dopants operative herein illustratively include fluorine, antimony, lithium, and transition group metals, lathanides, ions thereof, and combinations thereof.

A protected electrode linear plasma source technology is used for large area dielectric coating by PECVD. A suitable protected electrode linear plasma source is detailed in the resulting SnO₂ films show high deposition rate, excellent optical transparency and good adhesion and environmental stability. In comparison to current reactive sputtering technology, PECVD significantly improves the cost of ownership in material and energy savings for a number of important applications. This technology is linearly scalable and applicable to in-line systems.

An inventive plasma source technology illustratively operates with an AC mid-frequency power supply and features a hidden electrode that stays free of dielectric build-up during operation for deposition of tin oxides. The source is capable of conversion efficiencies of chemical precursors in excess of 30% resulting in low material costs and high precursor utilization. Operating between 1 and 25 millitorr, the source is compatible with sputtering processes. This low operating pressure also avoids harmful gas phase nucleation of particles that are problematic for sources that operate at pressures of 100 millitorr or greater. The high deposition rate, low material costs and energy efficiency of the source offer a compelling alternative to dielectric reactive sputtering processes.

Deposition rates are in excess of 50 nanometers per linear meter/min (nm-m/min) and can exceed 20, 100, 125, 150, and even 200 (nm-m/min) based on source operating conditions. Such films are readily deposited at 20° C. (293 K) to temperature of up to 700° C., and beyond if so desired. Substrates for deposition are varied owing to the mild deposition conditions and include glasses, silicon wafers, and polymeric materials. Polymeric materials illustratively including polycarbonate, polyethylene ter-phthalate, polybutylene ter-phthalate, poly methacrylate copolymers, and poly vinyl chlorides. The inventive process is well suited for deposition on a polymeric web that passes through at least one zone of PECVD.

Through resort to a linear plasma source with an internal electrode the deposition thickness is controlled by the speed of a substrate translation through the plasma region in which PECVD occurs in the presence of tetravalent tin precursor (e.g tetramethyl tin or tin tetrachloride) under suitable pressure and temperature conditions. With resort to a protected electrode source, long production runs occur on the order of tens or hundreds of continuous hours. Such linear PECVD sources are commercially available from General Plasma Inc, Tuscon, Ariz. Additionally, there is no need to perform a post deposition etch back of the deposited film, as is common in other deposition techniques. The resultant films are highly conformal with a thickness variation across 300 mm wide substrates of better than 5 thickness percent and often less than 2 thickness percent. Conformity of better than 5 thickness percent is achieved up to a 4 meter width substrate; with still wider substrates amendable to attaining this conformality.

Deposition of doped tin oxide films according to the present invention is readily performed using conventional dopant precursors metered into the linear PECVD source to achieve a steady state doping concentration. By way of example, sulfur hexafluoride, flour-alkanes, perfluoro-alkanes, fluorinated tetravalent tin precursors, tin tetrafluoride, and perfluoro-tetravalent organo-tin precursors are operative herein for fluorine doping. Typical fluorine doping levels are such that the resultant carrier concentrations range from 1×10¹⁸ to 1×10²² carriers per cubic centimeter. Precursors for metal dopants are conventional organo metallic and, metallic targets, and other precursors amenable to volatilization and decomposition under tin oxide precursor decomposition conditions in the linear PECVD chamber. Antimony, lithium, transition group metals, and lanthanides are provided to afford carrier concentrations that while varying based on saturation levels for a specific dopant are similar to those detailed above for fluorine.

Doped tin oxide is readily produced according to the present invention in which the resistivity, p, in Ohm-centimeters as a function of deposition temperature is

ρ<−4.6×10⁻⁵ (Ohm-cm/degree Kelvin)*(T)+0.01 Ohm-cm

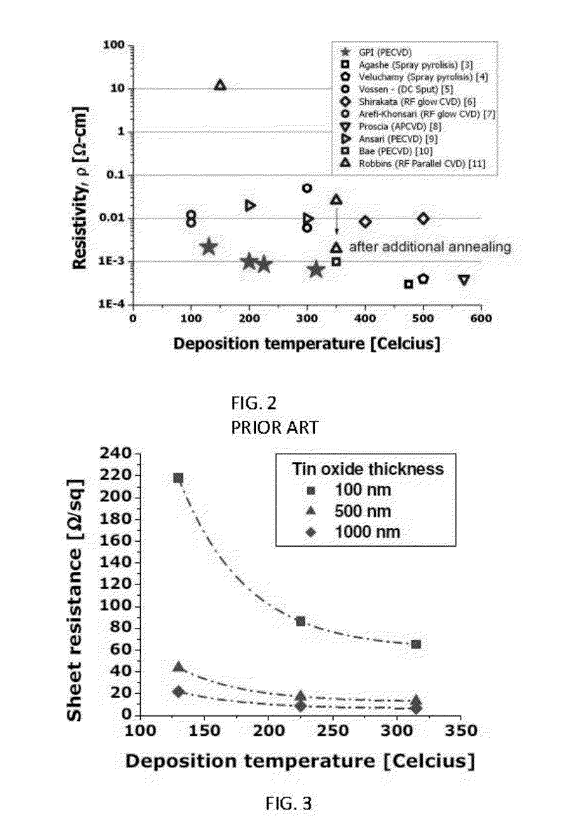

between 293 Kelvin and 673 Kelvin where T is in degrees Kelvin. The improved conductivity at a given deposition temperature for fluorine doped tin oxide is noted in prior art FIG. 2 for the compositions denoted with stars; also included in FIG. 2 are resistivity values for fluorine doped tin oxide produced by spray pyrolysis (open square and open pentagon), direct current sputtering (open circle), radio frequency glow enhanced CVD (open diamond and solid circle), atmosphere pressure CVD (inverted open triangle), conventional PECVD (sideways open triangle and filled square) and radio frequency parallel CVD (open triangle). It is of note that the data provided in FIG. 2 has been adjusted to compensate for thickness effects to resistivity.

### Example 1

Tin dioxide (SnO₂) films are deposited on glass, silicon and polymer substrates. The films are deposited using a laboratory 300 mm wide chill drum web coater. The coater features a 400 mm wide linear PECVD source and chill drum. The coater is aligned to have a 50 mm overlap on each side of the 300 mm width substrate web of polyethylene ter-phthalate (PET) passing by the coater. The high vacuum pumps are two 1200 L/s turbo pumps. Tetra methyl tin precursors are delivered by direct vapor to the source/substrate vicinity through a binary distribution manifold. Preferably, the linear plasma PECVD technology used herein is the precursor is delivered outside the source cavity practically eliminating deposition of coating on internal electrode surfaces. Deposition continues without degradation in film quality continuously for more than 24 hours.

A Filmetrics F20-UV spectrometer is used to measure both transmittance and reflectance of the deposited thin film and deduce the thin film thickness through optical modeling. Dynamic deposition rate is calculated from the known line speed. Index of refraction measurements are measured by both optical spectroscopy and a Metricon 2010M prism coupler at 632 nm.

Density of the thin films is evaluated by cross sectional SEM where the microstructure of the thin films is revealed.

Environmental stability is a key feature for many applications. Here the thin film is evaluated for adhesion, cracking and blistering after exposure to water or water vapor. Immersion tests in D.I. water for 30 minutes at room temperature and exposure to 85% RH/85 C for several days are common tests. Adhesion is evaluated by a standard iMii-Spec cross hatched grid test before and after exposure to the environmental challenge. The resultant coatings meet or exceed all current standards for photovoltaic tin oxide coatings for a given thickness.

### Example 2

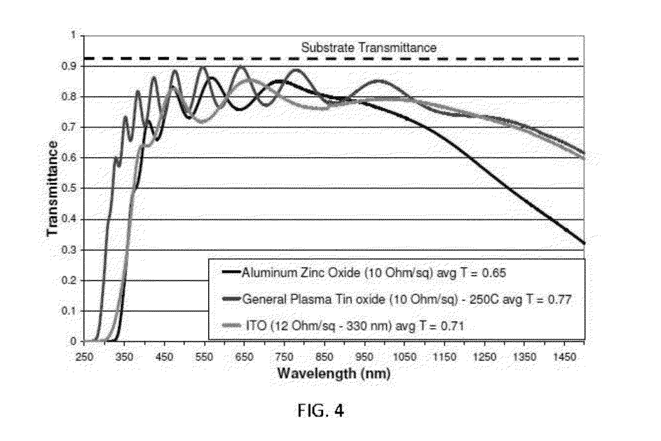

The process of Example 1 is repeated with addition of sulfur hexafluoride precursor being delivered by direct vapor to the source/substrate vicinity through a binary distribution manifold proximal to that delivering tetramethyl tin precursor. Sulfur hexafluoride is delivered to achieve a carrier concentration of 2×10²⁰ per cubic centimeter deposition onto a substrate at 50 nm per linear meter. The conductivity for 500 nm thick fluorine doped tin oxide as a function of deposition temperature is provided in FIG. 2. The sheet resistance as a function of deposition temperature in degrees Celsius is provided in FIG. 3 where sheet resistance is provided in Ohms per square centimeter. FIG. 3 provides sheet resistance for tin oxide thicknesses of 100 nm (solid square), 500 nm (solid triangle) and 1,000 nm (solid diamond). Optical transmission of fluorine doped tin oxide produced according to the present invention having a sheet resistance of 10 Ohms per square centimeter per FIG. 3 has a transmittance profile across the visible and infrared spectra that is superior to that of aluminum zinc oxide having the same sheet resistance and indium sheet oxide having a sheet resistance of 12 Ohms per square centimeter and a thickness of 330 nm. These comparative results are provided in FIG. 4 where the doped tin oxide according to the present invention has a transmittance across wave length spectrum averaging 0.77, as compared to 0.65 and 0.71 for aluminum zinc oxide and indium tin oxide films, respectively.

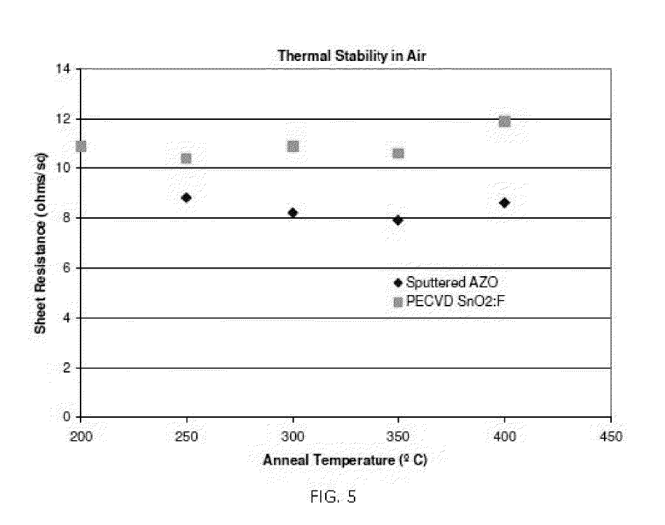

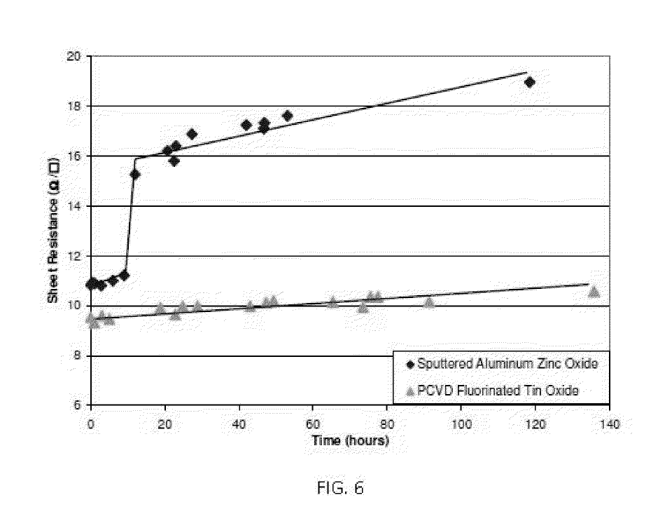

The superior thermal stability in air of fluoride doped tin oxide produced according to the present invention as compared to magnetron sputtered aluminum zinc oxide is depicted in FIG. 5 as a function of anneal temperature. It is of note that fluorinated tin oxide produced by prior art techniques not always shown superior thermal stability in air as compared to aluminum zinc oxide. The resultant film is also exposed to 90% relative humidity at 50° C. in an environmental weathering chamber to assess environmental stability that might be experienced in a photovoltaic usage. Fluorinated tin oxide produced by this example shows superior environmental stability to magnetically sputtered aluminum zinc oxide, as shown in FIG. 6.

Owing to the comparative cost of tin oxide precursors and other consumables associated with PECVD, considerable efficiencies are produced compared to aluminum zinc oxide and indium tin oxide produced magnetron sputtering that use comparatively expensive sputter targets that have poor target utilization.

Any patents or publications in this specification are indicative of the levels of those skilled in the art to which the invention pertains. These patents and publications are herein incorporated by reference to the same extent as if each individual patent or publication was specifically and individually indicated to be incorporated by reference.

The foregoing description is illustrative of particular embodiments of the invention, but is not meant to be a limitation upon the practice thereof. The following claims, including all equivalents thereof, are intended to define the scope of the invention.

1. A process for deposition of a tin oxide film comprising: decomposing a tetravalent tin precursor under conditions of plasma enhanced chemical vapor deposition in a linear plasma source onto a substrate moving through a plasma generated by said linear plasma source to deposit the tin oxide film with a linear uniformity of thickness that varies by less than 5 thickness percent across said substrate, said substrate having a width of greater than 30 cm.

2. The process of claim 1 wherein the depositing occurs at less than 350° Celsius.

3. The process of claim 1 wherein said rate is greater than 20, 100, 125, 150, 175 or 200 nm-m/min.

4. The process of claim 1 wherein said tin film is SnO₂.

5. The process of claim 4 wherein said rate is greater than 20 nm-m/min.

6. The process of claim 1 wherein the linear plasma source for the depositing operates at a pressure of between 1 and 100 millitorr.

7. The process of claim 1 further comprising doping the tin oxide film to render the tin oxide film electrically conductive.

8. The process of claim 7 wherein the doping occurs simultaneous with the decomposing of the tetravalent tin precursor.

9. The process of claim 8 wherein said tin oxide film is fluorinated.

10. The process of claim 1 wherein the tin oxide film is deposited in said substrate with a linear uniformity of thickness that varies by less than 2 thickness percent across said substrate, said substrate having a width of between 0.3 and 4 meters.

11. The process of claim 1 wherein the tin oxide film is deposited continuously for more than ten hours.

12. The process of claim 1 wherein the tin oxide film is deposited continuously for more than twenty-four hours.

13. A composition comprising:
a substrate;
a tin oxide film having a linear uniformity of thickness that varies by less than 5 thickness percent across a substrate width of greater than 30 cm, said tin oxide film containing a dopant at a dopant concentration such that said tin oxide film has a resistivity as a function of film deposition temperature of less than −4.6×10⁻⁵ Ohm-centimeter per degree Kelvin (T) plus 0.01 Ohm-centimeter where T is between 293 Kelvin and 673 Kelvin.

14. The composition of claim 13 wherein the linear uniformity of thickness varies by less than 2 thickness percent across the substrate width.

15. The composition of claim 13 wherein said dopant is fluorine.

16. The composition of claim 15 wherein said dopant concentration is between 1×10¹⁸ and 1×10²² carriers per cubic centimeter.

17. The composition of claim 13 wherein said dopant is at least one of antimony, lithium, a transition metal, or a lanthanide.

18. The composition of claim 13 wherein said tin oxide film has a cassiterite crystalline structure.

19. The composition of claim 13 wherein the substrate width is up to 4 meters.
